(19) United States
(12) Patent Application Publication
(10) Pub. No.: US 2009/0073662 A1
(43) Pub. Date: Mar. 19, 2009

(54) Weather cover for electronic equipment, use thereof for hanging on a mast tower, or mono-pole, and antenna carrier for weather cover

(76) Inventor: Bo-Gunnar Dahl, Ostersund (SE)

Correspondence Address: BIRCH STEWART KOLASCH & BIRCH, PO BOX 747, FALLS CHURCH, VA, 22040-0747, US

(21) Appl. No.: 11/666,067

(22) PCT Filed: Oct. 21, 2005
(86) PCT No.: PCT/SE05/01590

§ 371 Date: Sep. 12, 2007

(30) Foreign Application Priority Data
Oct. 22, 2004 (SE) 0402575-5
May 10, 2005 (SE) 0501066-5

(51) Int. Cl. H05K 7/20; H05K 5/02

(52) U.S. Cl. 361/724; 361/690

(57) ABSTRACT

Weather cover for electronic equipment designed to be mounted on towers, hanged on masts, towers or mono-poles, which weather cover (10) comprises: a housing (1) that can be opened for service or the like thereof, said housing (1) comprising at least one side (2) that can be opened, which side (2) comprises at least one access door (2a), mounted (hinged) in the housing (1) such that it provides an opening of, or closes the housing (1), between electronic equipment (3) mounted therein, which weather cover (10) further comprises mounting means for hanging said weather cover (10).

### TECHNICAL FIELD

The present invention relates to a weather cover for hanging on a mast, tower, or monopole. The present invention also relates to an antenna carrier device for weather covers.

### BACKGROUND

Electronic equipment such as telecommunication equipment must be protected against surrounding weather, i.e. climate influences due to rain, snow, dust and other particles and insects present in nature. Often, also shielding of the equipment is necessary. Because of that such equipment is often mounted in suitable weather covers or houses, so-called technology houses, shelters, enclosures or other types of weather covers.

When for instance a base station for a telecommunication system is installed, it is desirable that the installation can be performed as quickly and easy as possible. A quick installation reduces for instance the cost for establishment and makes it possible to get the base station ready for operation earlier. Less installation on site is of great importance because electronic equipment normally is very sensitive to dirt and water, whereby on site installation has to be reduced as much as possible.

Today, the electronic equipment for a base station, which equipment comprises radio base transmitter, rectifiers, alarms and climatisation devices, is installed in different weather covers of different sizes. These are provided in different designs in the form of containers of steel, technology houses in different designs, and heavy concrete constructions, all suffering from the fact that they have to have foundation provided separately. The weather cover is connected to antennas by means of cables, so-called feders and jumpers, being connected to the antennas mounted on an external antenna carrier such as a mast, tower or a monopole. The electronic base station equipment is installed after the weather covers have been placed on the site for transmission equipment, the “site”, depending on different difficulties to provide the electronic base station equipment in the weather cover complete and ready to operate, which implies that water, vapor and dirt may penetrate into the sensitive electronics. It may also be damaged because of many reloads and transports on bad roads or on no roads at all such as bad forest roads or when lifted to roofs or at other applications.

Since the electronic equipment often has to be installed on sites hard to reach outdoor, also the installation of these bulky weather covers implies a considerable effort. For instance, much time is spent on foundation of the weather cover, connecting and equipping the same, in connection to long installation times to get the equipment ready for operation, instead of delivering the complete electronic equipment including the weather cover directly to the site. This implies that for instance the cost for a new installation of a mobile communication system, for instance 2 or 3G, would be lower in relation to present conditions if that could be avoided.

Often, not to say always, the construction and design of weather covers of today, are not adapted to the environment in an efficient manner, the cooling devices are often mounted outside the weather covers on a wall thereof, which makes the weather cover having an even worse appearance because of large additional external units.

Present technology has a number of disadvantages and problems, whereby the object of the present invention is to solve or at least improve present technology.

### SUMMARY OF THE INVENTION

An object of the present invention is to provide a weather cover for electronic equipment, which weather cover is not bulky, but compact och has lower weight than existing weather covers, thereby primarily providing mounting and hanging on masts, towers, mono-poles, buildings and roofs.

Another object of the present invention is to provide a complete weather cover provided with electronics.

A complete weather cover provided with electronics is very well suited for extending already constructed sites, so-called “sites”, by means of using present masts, towers or mono-poles to hang the weather cover thereon without the need of any own foundation. Such extension is more complicated with conventional weather covers since these are not adapted to be hanged on masts, towers or mono-poles, but have to have their own separate foundation.

Another object of the present invention is to provide a weather cover for electronic equipment, which is suitable for service outdoor even during bad weather conditions such as rain, snow, sand storm etc.

The expression “weather cover” relates to all types of structures being designed to in a suitable way protect electronic equipment against surrounding environment.

According to a first aspect of the present invention, there is provided a weather cover for electronic equipment, said casing being arranged to be mounted, hanged on masts, towers, or monopoles, said weather cover comprising:

a housing that can be opened for service or the like thereof, said housing comprising at least one side that can be opened, which side comprises at least one access door, mounted hinged in the housing such that it provides an opening of or closes the housing, between electronic equipment mounted therein, which weather cover further comprises mounting means for hanging said weather cover.

In this way, a weather cover is provided that can be as small as possible such that the electronic equipment precisely fits into the same, by means of the electronic equipment in the form of radio base station, alternatively radio base stations, and rack for electronic equipment are placed on each side of the door, such that the space provides access to the electronic equipment inside the weather cover and between the equipment for a user such as personnel for repair or installation. It is of great importance that the weather cover is as small as possible and has such a low weight that it is suitable for mounting the same (at all is provided to be mounted) directly on masts, towers, buildings, roofs or mono-poles.

This is a great difference to earlier known “smaller” apparatus boxes for mounting hanging, such as main electric boxes etc, which does not provide a user to enter the box to be protected against the weather.

By means of this, already existing infrastructure of the mast, tower or mono-pole is employed, which is of great importance, for instance because of cost.

The low weight makes it possible to fully provide the weather cover with proper electronic equipment in factory, whereafter the weather cover is transported by means of a truck for instance or other means of transportation. In this way, one avoids the problem with installation of sensitive electronic equipment in a bad environment that is not suitable for such equipment. The quality of the installation could therefore normally be increased to a large extent compared to conventional installation on site, on the roof or other installation. In this way, user are able to work protected against weather inside the weather cover similar to conventional present technology. However, present technology has considerably bulkier and heavier constructions, impossible to mount hanging, such as bulky steel containers.

The weather cover according to the present invention could be provided around an antenna carrier, mast, tower or mono-pole and be hanged such that the foundation of the antenna carrier provides the foundation and support for the weather cover, which makes foundation of the weather cover not necessary in this case. The weather cover could be applicated as a separate unit or in multiple units on the antenna carrier. In this way, the length of feders could be short and bending of the same could be totally eliminated, which provides improved transmission signals and easy protection against falling ice from the antenna carrier.

According to a second aspect of the present invention, the weather cover comprises at least a first door and a second door, said doors being arranged hinged in the housing such that they together provide an opening of or closes the housing, characterised in that the doors substantially are conform and arranged to from a vertical position turn upwards and downwards, respectively, to a substantially horizontal position in respect of the normal position in use of the housing, and that movable shielding means when the doors are open are provided to connect the thereby obtained free edges of the doors and during service of the electronic equipment for instance being arranged to provide a space for the service personnel och together with the housing provide a weather cover for the electronic equipment as well as for the service personnel.

This second embodiment of the weather cover according to the present invention possesses the same advantages as the previous described embodiment of the weather cover of the present invention. In this second embodiment of the present invention, however, the weather cover is still more improved, because the access door is provided in the form of a “lock” having side walls, roof and floor.

Preferably, the first door is arranged to provide a roof and the second door is arranged to provide a floor in an open position in use thereof.

Preferably, the movable shielding means are foldable.

Preferably, the shielding means comprises two parts, which in extended, upfolded position are arranged to provide a protective weather cover for a user.

Preferably, the second door is provided with locking means for locking the door in an open position, wherein said locking means is/are provided to in an open position support at least the load of two persons and electronic equipment.

Preferably, the locking means comprises at least one foldable bar provided between an edge and the second door and an inner side of the housing, whereby the foldable bar in unfolded position keeps the second door in a substantially horizontal position.

Preferably, the second door is provided with built-in damping means such as gas attenuators, which are adapted for damping the velocity of the second door when folded down, and to support folding up the same.

Preferably, the second door is arranged to be foldable towards the ground to provide a ramp for heavy goods, preferably by controlling a locking means, such as a sprint provided for this.

Preferably, the weather cover is provided with a temperature control device, which comprises means for temperature control, preferably for cooling the electronic equipment in the weather cover, whereby the temperature control device is provided as a wall of the housing, preferably the roof and preferably being provided with lifting means, such as lifting loops, such that it easily can be removed or mounted to the housing.

Preferably, the temperature control device is arranged to operate with ambient air as cooling medium or with actively controlled cooling or a combination thereof.

Another aspect of the present invention is directed to the use of at least one weather cover according to any one of the preceding claims to be hanged on an antenna carrier, mast, tower, or mono-pole, in particular the use of two or more weather covers.

Yet another aspect of the present invention relates to an antenna carrier for electronic equipment, on which antenna carrier a weather cover having the features as above is mounted and hanged.

The invention provides a weather cover and use thereof providing essential advantages within most of the operative fields, and which provides improved logistic and economy.

The invention will now be described by way of non-limiting embodiments with reference to accompanying drawing figures, in which:

### SHORT DESCRIPTION OF DRAWING FIGURES

FIG. 1 shows a weather cover according to a first embodiment of the present invention, in a frontal view.

FIG. 2 shows the same embodiment as is shown in FIG. 1 in a view from the side.

FIG. 3 shows the same embodiment as is shown in FIG. 1 och 2 from above, showing three weather covers mounted on a mast at the same time.

FIG. 4 shows the same embodiment of the present invention in a perspective view, showing the access door opened and having connection to an external antenna carrier and mounted hanging on the same.

FIG. 5 shows the same embodiment of the weather cover according to the present invention in a perspective rear view, provided with connection to an external antenna carrier and mounted hanging on the same.

FIG. 6 shows three weather covers mounted hanging on an antenna carrier.

FIG. 7a shows a weather cover according to a second embodiment of the present invention in a perspective view.

FIG. 7b shows the second embodiment of the present invention in a frontal view provided with movable shielding means (including sides) visible.

FIG. 7c shows the same embodiment as shown in FIG. 7b in a perspective view.

FIG. 8 shows the same embodiment as is shown in FIG. 7a in a view from the side.

FIG. 9 shows the same embodiment as is shown in FIG. 7a-c and FIG. 8, in a perspective view, but with the side walls in a folded out position.

FIG. 10 shows an embodiment of the present invention in a sectional side view, showing the side walls in a folded out position and having connection to an external antenna carrier, mast or tower.

FIG. 11a shows an embodiment of the weather cover according to the present invention in a perspective view from below.

FIG. 11b shows the same embodiment as is shown in FIG. 11a in a frontal view.

FIG. 12a shows a weather cover mounted hanging with hanging mounting means according to an embodiment of the present invention on an antenna carrier, and

FIG. 12b-g show the hanging mounting means in more detail.

FIG. 13 shows the weather cover according to FIG. 11 a in a rear perspective view.

FIG. 14 shows the weather cover according to FIG. 11a in a frontal perspective view.

FIG. 15 shows three weather covers arranged on a mast.

### DETAILED DESCRIPTION OF EMBODIMENTS OF THE INVENTION

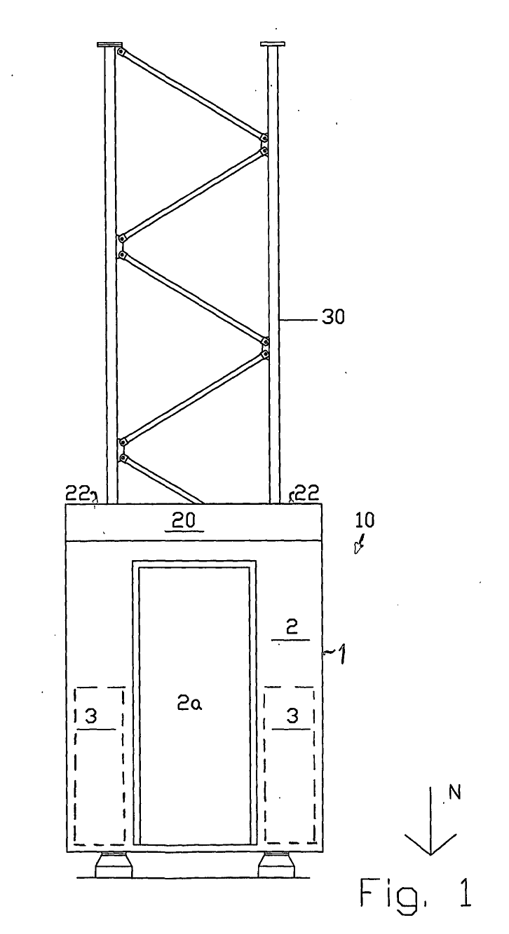

Referring to FIG. 1, an embodiment of the present invention mounted hanging on a mast in the form of a weather cover 10 for electronic equipment 3 and user's thereof, which weather cover 10 comprises a protective housing 1 surrounding the electronic equipment 3 (herein only schematically showed by dashed lines), having a side 2 that can be opened.

The side that can be opened comprises an access door 2a, which can be pivoted outwards in relation to a normal direction N (shown by means of an arrow) the weather cover 10 has during use thereof. “Access door” relates to all types of doors or similar having one or more door elements and the invention is by no means limited the access door as shown in FIG. 1.

Inside the access door 2a, the electronic equipment 3 can be placed on each side of the door 2a having the radio base station to the right or to the left of the door and a 19″ rack for rectifiers, transmission and power supply on the opposite side to the left or to the right of the door (as seen in the figure).

Between the radio base station and the 19″ rack, there is provided a space, which precisely provides space for service personnel and their need. Here, the personnel can work, protected from rain, snow, wind and sand storms, with the sensitive equipment.

Conventional, “compact” weather covers having doors that may pivot side-ways, such as conventionally mounted doors do not provide protection of the user from the surrounding environment. Instead, there must be provided additional protective equipment such as surrounding tents or the like adjacent to the conventional weather cover, which of course provides a number of disadvantages. Without such protective equipment, there is a risk that water penetration through the weather cover occurs, which may lead to damage of the equipment besides the fact that the user feels the environment is not comfortable.

FIG. 1 also shows a mast 30, on which the weather cover 10 is hanging, and a temperature control device 20.

It is the combination of low weight, small box, factory mounted equipment, mounting hanging on mast, tower or mono-pole, which provides the advantages of the present invention.

Moreover, a weather cover complete and equipped with electronics is very well suited for extending already built transmission stations, so-called sites, by means of using already existing masts, towers or mono-poles for mounting the weather cover hanging, which does not require separate foundation. Such extension is more complicated by means of conventional weather covers because these are not suitable for mounting hanging on masts, towers, roofs or mono-poles, but must be founded separately.

The temperature control device 20 is arranged such that it may constitute a wall of the housing 1, preferably the roof and is preferably provided with lifting means 22 such as lifting slings such that it easily can be removed or mounted to the housing 1, for instance by means of conventionally operating bayonet locks, or the like.

The temperature control device 20 does not have to be part of the roof but may, even if it is not preferred, be mounted as a side wall or even be completely omitted, provided a conventional cooling box is mounted instead, which is not preferred, but possible.

The temperature control device 20 is arranged to operate with air as cooling medium only, or alternatively with actively controlled cooling. This is not described in more detail, since it is obvious for a person skilled in the art. In this way, service for instance, of the temperature control device may easily be provided by means of changing the roof part each time service is necessary. Of importance is that the temperature control device compared to present such cooling devices for electronic equipment may operate actively or passively depending on demand. Active cooling may for instance be activated a period for instance a hot day and inactivated a cooler period, for instance during the night.

The weather cover may also alternatively comprise a controlled fan and a filter and a heating device for the air to obtain as even temperature as possible (which is not shown). In this case, the temperature control device operates with the air only as cooling media.

Preferably, the weather cover comprises at least a filter, placed such that the filter could be positioned in the space next to the other equipment, alternatively between the equipment or on one of the walls of the weather cover such as the roof.

In FIG. 1 is also shown how the electronic equipment 3 (herein telecommunication equipment for mobile telephony) preferably could be connected to an antenna carrier (which is not shown) by means of connecting means arranged directly in the upper part of the housing above the electronic equipment 3.

By means of this connection cumbersome mounting on site are avoided. Preferably, crimped antenna cables so-called “jumpers” are mounted directly in the factory and are connected to the electronic equipment. Holes for the crimped antenna cables are also provided in the factory. On site, these crimped antenna cables are connected to the antenna carrier with coarser antenna cables (feders) connected to the antennas mounted on the antenna.

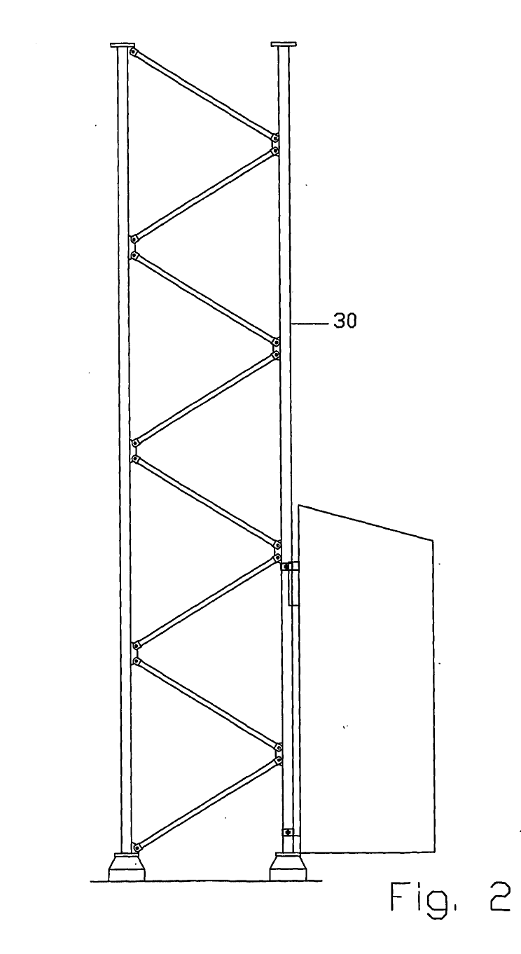

Now is referred to FIG. 2, which shows the mounting on mast 30 (antenna carrier) in a view from the side.

The compact weather cover is mounted directly on the antenna carrier 30 and should be regarded as part of the same, the design is directly adapted to the requirements such that it fits the antenna carrier 30 in a natural way and being part of the same. This is an advantage because the antenna links are shorter having better transmission properties and cost less.

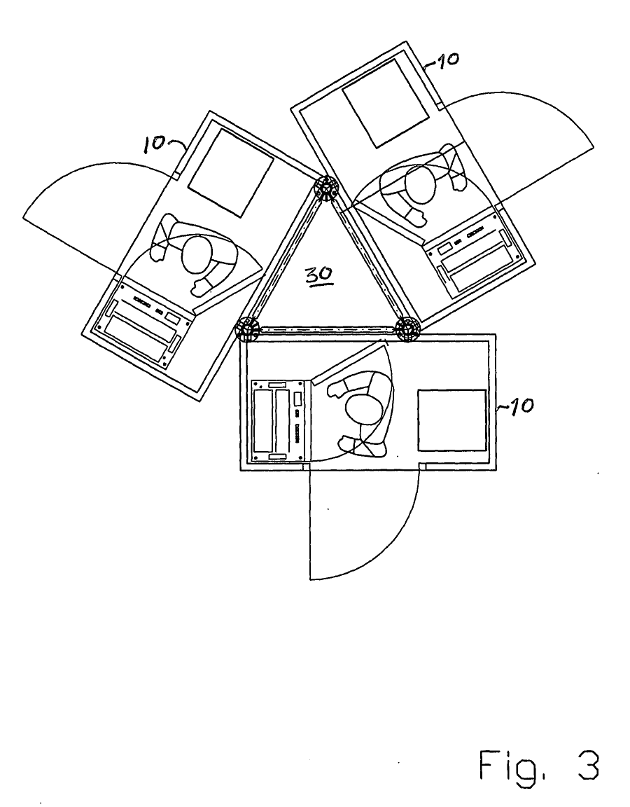

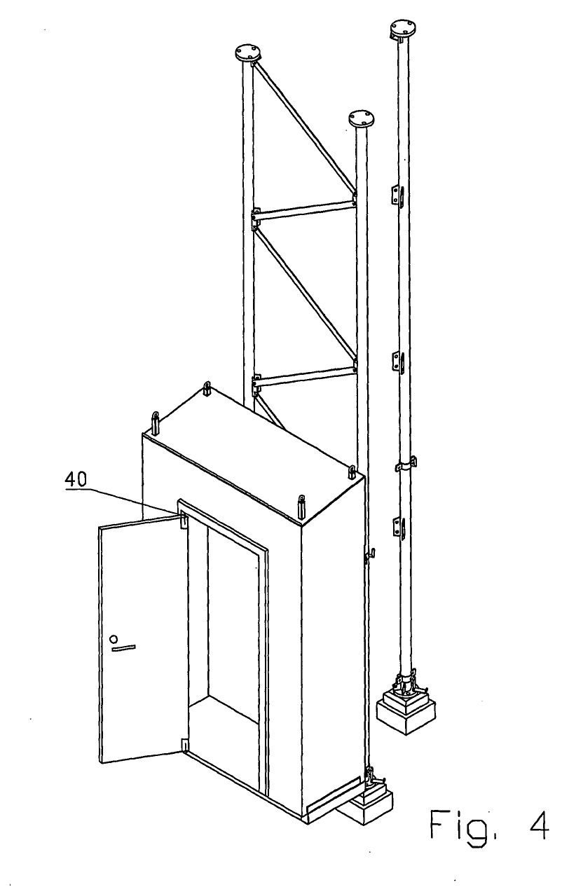

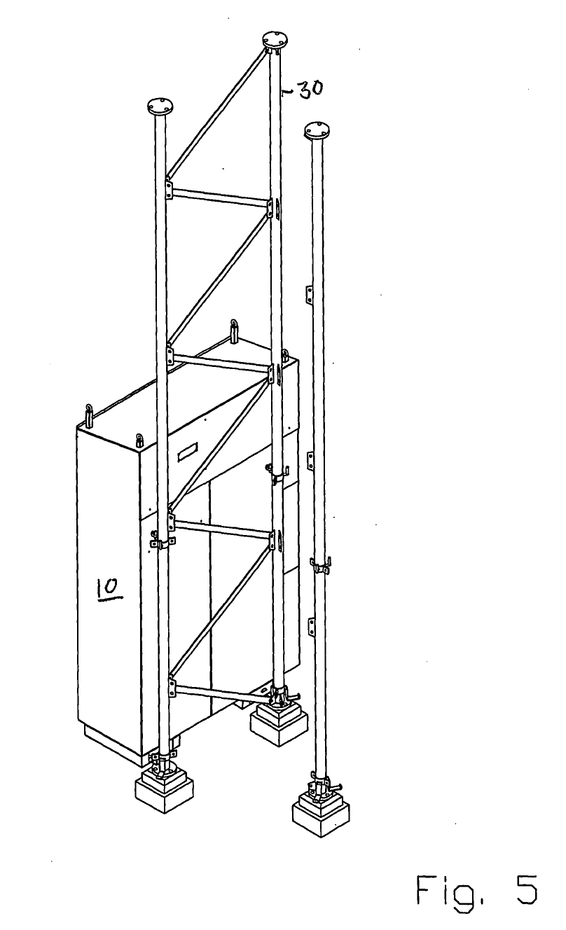

FIG. 3 shows the same embodiment as is shown in FIG. 1 and FIG. 2 in a plane view from above showing three weather covers 10 mounted simultaneously on a mast 30. Here, an embodiment of the present invention is shown, comprising an antenna carrier (mast) 30, on which three weather covers 10 are mounted hanging.

FIG. 4 shows a weather cover 10 according to an embodiment of the present invention having the access door 2a opened and being connected to an external antenna carrier 30 and being mounted hanging on the same. The antenna carrier 30 may for instance be a mast, tower or mono-pole.

In FIG. 4 there is also shown a preferred mounting means 40 for the access door 2a. The mounting means 40 comprises a spring tensioned cylindrical rod provided in both the door 2a and the side 2, whereby the mounting means 40 extends in the same plane. However, this does not exclude conventional hinged mounting means.

FIG. 5 shows an embodiment of the weather cover in a perspective rear view, connection to an external antenna carrier 30 and mounting hanging on the same.

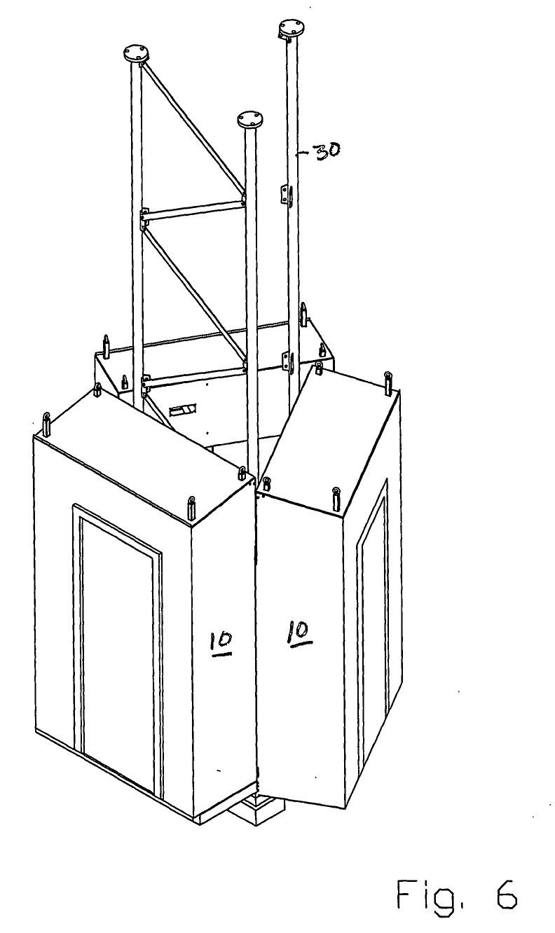

FIG. 6 shows the same embodiment showing three weather covers 10 mounted hanging on one and the same antenna carrier 30 close to ground. It is also possible to mount the weather covers hanging above the ground, even if this is not shown in this drawing figure. It is also possible to provide a platform or the like, even if this is not shown in any drawing figure.

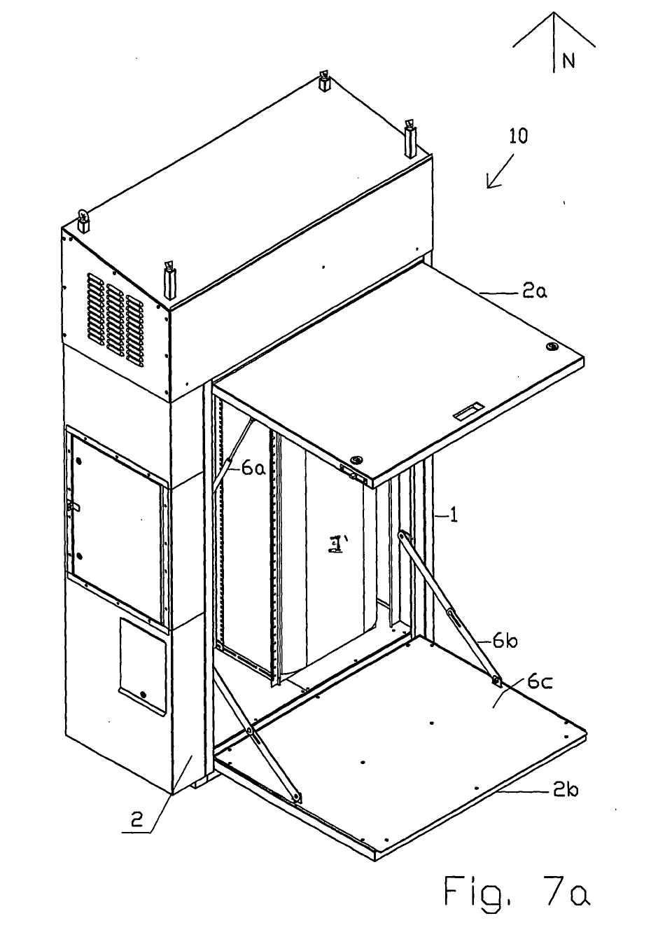

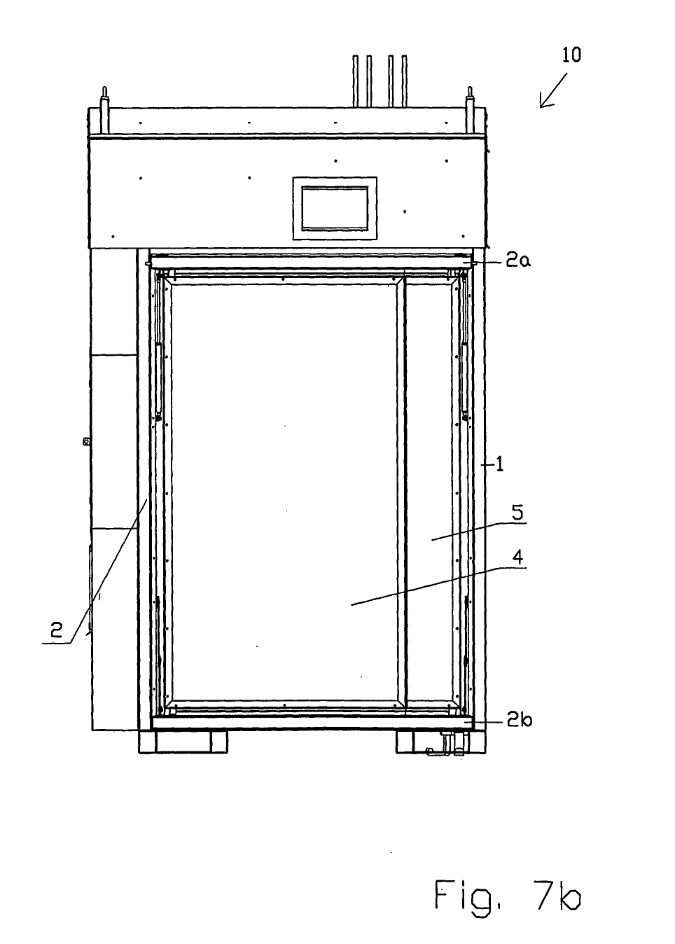

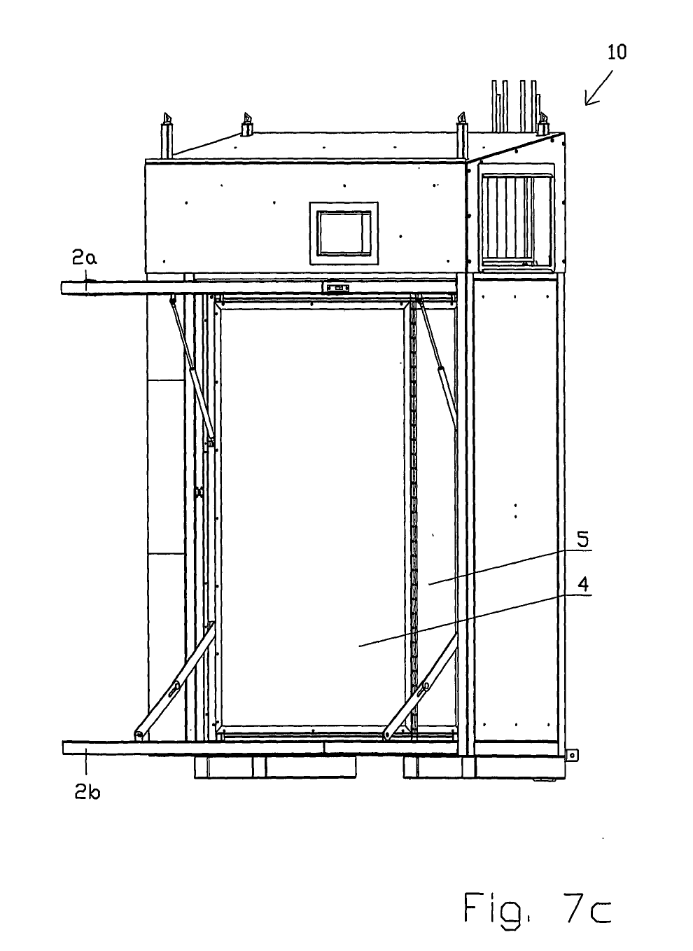

Now referring to FIGS. 7a and 7b there is shown a second embodiment of the present invention in the form of a weather cover 10 for electronic equipment 3 and users thereof, which weather cover 10 comprises a protecting housing 1 surrounding the electronic equipment 3 (herein only schematically shown in FIG. 7a), having one side 2 that can be opened. FIG. 7a shows the weather cover in a perspective view without visible shielding means, but FIG. 7b showing a frontal view, shows these visible. FIG. 7c shows the same embodiment as is shown in FIG. 7b in a perspective view, whereby the shielding means are shown.

The side 2, that can be opened comprises a first access door 2a, and a second access door 2b, which are pivotable mounted upwards and downwards in relation to a normal direction N (shown by means of an arrow) the protective weather cover 10 has when in use (see FIG. 7a).

When the doors 2a, 2b are opened, the electronic equipment 3 is protected by means of movable shielding means 4, 5 (see FIG. 7b), which are arranged inside the doors 2a, 2b, which shielding means 4, 5 are arranged and designed to together with the housing 1 provide a weather cover for the electronic equipment (and users thereof), which shielding means 4, 5 are arranged to together with the doors 2a, 2b in open position protect the electronic equipment 3 (see both FIG. 7a och 7b).

The shielding means 4, 5 (see FIG. 7b och 7c) are arranged so that, for instance by means of being telescopic extendable, could be push-/pullable and/or foldable, and/or pivotable, they could be pulled out by means of a user, while protecting the electronic equipment.

The design of the shielding means 4, 5 and suitable arrangement of the same inside the doors 2a, 2b is only described briefly, since it is obvious for a person skilled in the art to design depending on application. Depending on for instance different rules relating to electric security, different length of security distance is required, which means that lengths etc of the shielding means 4, 5 have to be adapted thereto. According to certain rules, for instance, a certain security space must be present for users. Because of that, lengths and material are preferably adapted depending on present rules and other requirements.

By means of the design of the doors 2a, 2b, there is provided a weather cover 10, which is compact since the housing 1 can be as small as possible, just to accommodate the electronic equipment 3 inside the same, because the doors 2a, 2b, when opened, provide good access to the electronic equipment 3 inside the housing 1 for users (not shown). Since one of the doors 2a is a roof for the users, they may work protected from rain, snow etc. The other door 2b is designed such that it provides a floor, onto which the users may stand during work, such that good comfort for the users is obtained.

Conventional “compact” weather covers having doors being pivotable side ways, such as conventional hanged doors do not have the feature to protect the user from surrounding environment. Instead, conventional weather covers must have surrounding tents or the like arranged adjacent to the weather cover, which of course implies a number of disadvantages. Without such protective equipment, there is a risk for water penetration, which may harm the equipment despite the fact that the user does not feel the environment as comfortable.

Preferably, the doors 2a, 2b are held in open position by means of first locking means 6a, which for the upper door 2a, for instance may be of gas attenuator type. Preferably, a pair of gas attenuators 6 are provided in a manner known per se such that the upper door 2a is easy to open and close, but without difficulty could be held in open position. This is not further described, since it is obvious for a person skilled in the art to design such gas attenuators or similar locking means for doors of the type shown in FIG. 7a-b according to an embodiment of the present invention.

The expression “locking means” relates to all types of devices suitable for holding doors in open position and does not necessarily mean that a “locking” of the door is provided. Thus, the expression “locking means” should be broad and is by no means limited to a locking function only.

The second door 2b is also provided with locking means, herein referred to as second locking means 6b, of a more powerful type than the one related to the first door, when users, and their equipment preferably have to placed on the second door for instance during service or exchange of the electronic equipment, without the second door changing position to a large extent.

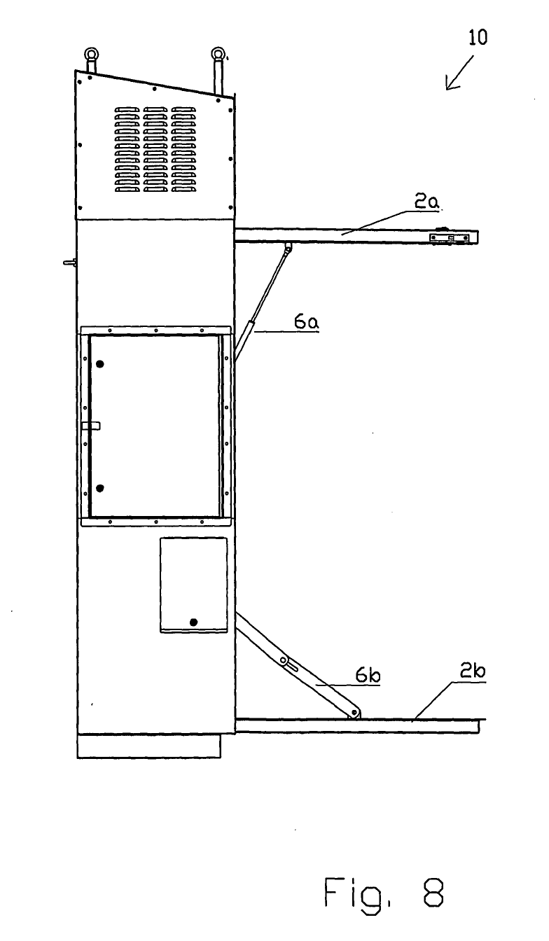

Preferably, these second locking means 6b are of the type locking bar, dimensioned to in open position accommodate the weight of at least two users and electronic equipment on the second door 2b. This is not described in more detail since dimensioning and design of such second locking means 6b are obvious for a person skilled in the art. The design of the locking means 6a, 6b is even more described in relation to FIG. 8, to which now reference is made. FIG. 8 is view from the side of the weather cover shown in FIG. 7a-b, in which it is shown how the doors 2a, 2b are arranged to the locking means 6a, 6b and how these for instance may be designed.

Preferably, the second door 2b is provided with built-in gas attenuators (not shown in more detail), which are provided to damp the velocity of the second door 2b when opening the same, and to support closing the door. Preferably, the second door 2b may also be provided to hit ground by means of pulling out a pin (or similar locking means), such that it provides a ramp feature. The ramp feature is preferred for instance for certain base stations because a present RBS (radio base station) often weights hundreds of kilograms. Without the ramp feature, it is not without difficulty that for instance two users are able to lift such equipment in/out.

The ramp feature is not shown in more detail in the drawing figure, because it is easy for a person skilled in the art to understand using the previous description.

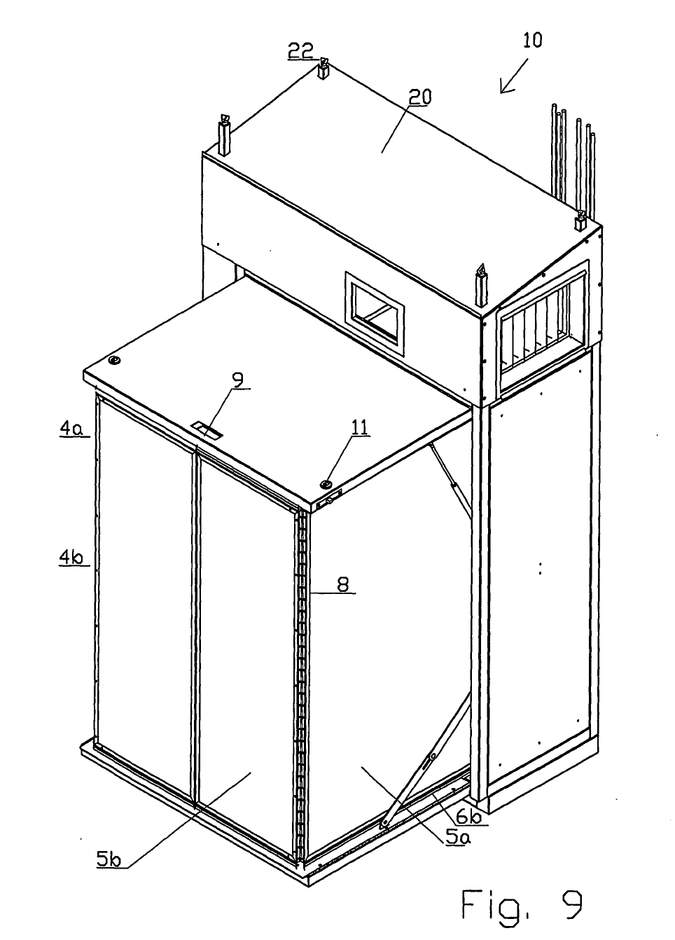

In the doors, rail means 6c are arranged (FIG. 7a-b) (of which only the ones provided on the second door 2b are shown), against which side ways telescopically extendable and/or foldable shielding means (not shown), herein sides, may be provided and locked to strengthen the weather cover even more, when the doors 2a, 2b are open. This is shown in more detail in FIG. 9, to which reference now is made.

FIG. 9 shows the same embodiment of the weather cover 10 as is shown in FIGS. 7 and 8, comprising shielding means (sides) 4, 5 that can be opened, each shielding means comprising a respective pair of sides 4a, 4b and 5a, 5b, respectively, herein shown by means of all being in opened position, whereby the first side is hidden, but shown by means of an arrow 4a. FIG. 9 shows for instance a situation when a user (for instance a service person) is present inside the weather cover and thereby is completely surrounded by the housing 1, comprising the shielding means 4, 5 that can be opened.

Preferably, the sides 4, 5 could be fastened and locked in the rail means 6c, and/or other suitable fastening means and/or rail means.

Preferably, each pair of sides, for instance the latter pair 5a, 5b are arranged to each other by means of foldable fastening means 8 such as scharnier or the like providing a user to easily pull out or in these sides 5a, 5b of the housing 1 by means of hand applied force despite surrounding environment comprising hard wind etc. Preferably, the sides are mounted by means of suitable powerful fastening means, such that a proper function is obtained, almost independent of influence from surrounding environment. This is not described in more detail since dimensioning and choice of material is evident for the person skilled in the art.

Preferably, the housing 1 including the pair of sides 4a, 4b, 5a, 5b are made of sheet metal, for instance corrosion resistant sheet metal, or hardened glass, plastics etc, and provides shielding of the electronics, but also other suitable materials and surface coatings may be employed. Dimensions of the sheet metal etc are not explained in more detail, since dimensioning and choice of material is evident for the person skilled in the art.

In FIG. 9, there is also shown a handle 9 and lock 11 provided for opening/closing the door, in this case the first door 2a. In the drawing figure, the design of a preferred temperature control device 20 is also shown. Preferably, the temperature control device 20 comprises means for climatising, typically means for cooling the electronic equipment in the weather cover.

The temperature control device 20 is provided such that it provides a wall of the housing 1, preferably the roof and is provided with lifting means 22 such as lifting slings such that it easily could be removed or mounted to the housing 1, for instance by means of conventional locks or the like. The temperature control device 20 does not have to be the roof, but may also, even if not preferred, be mounted as a side wall or may even be non-present, if a conventional cooling box is mounted instead, which is not preferred, but possible.

The temperature control device 20 is arranged to operate with air as cooling media or alternatively by means of actively controlled cooling. This is not described in more detail, because it is evident for a person skilled in the art. Because of that, for instance service of the temperature control device could easily be provided by means of exchanging the roof each time service is to be performed. Of importance is that the temperature control device compared to present technology of such cooling devices provided for electronic equipment could operate actively or passively depending on the demands. For instance, active cooling could be activated a period of time a hot day, and inactivated during a cooler period of time, for instance during the night. This provides obvious decrease in energy, which is of importance because of the large number of sites to be built for mobile telephone network coverage.

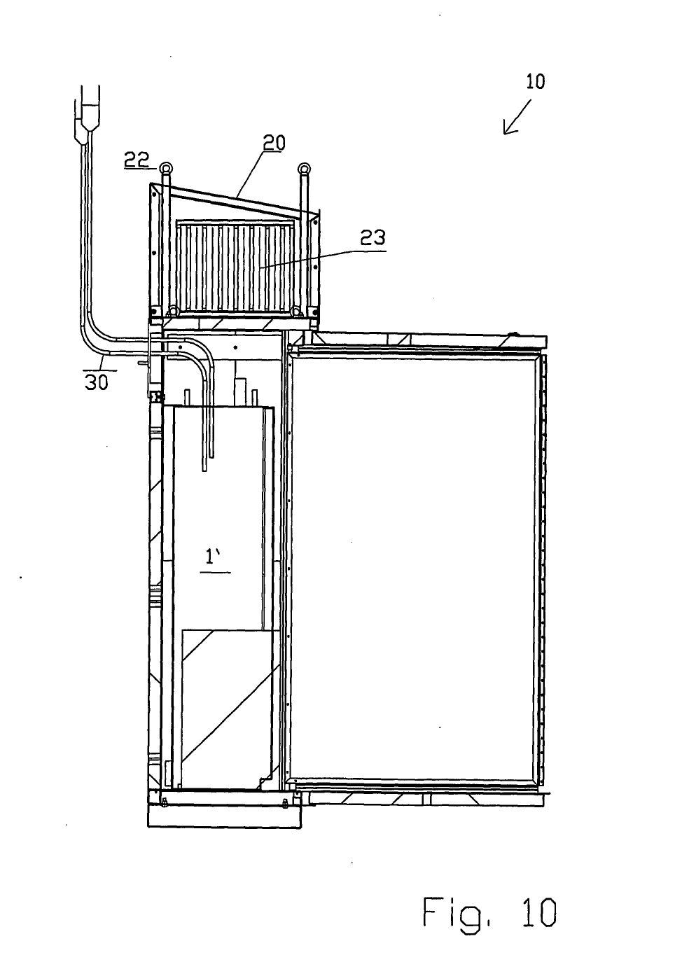

FIG. 10 is a sectional view showing the weather cover 10 according to an embodiment of the present invention from the side 10. Here, in even more detail, the design of the temperature control device 20 is shown, also illustrated in section, having the cooling means 23 visible. Here, in even more detail, a preferred attachment of the lifting means 22 is shown, even if modifications may be performed without departing from the invention. In FIG. 10 is also shown how the electronic equipment 3 (herein telecommunication equipment for mobile telephony) preferably could be connected to antenna carriers (not shown) by means of connecting means 30 provided directly in the upper part of the housing above the electronic equipment 3.

By means of this connection, cumbersome mounting are avoided on site. Preferably, crimped antenna cables, so-called jumpers are mounted at factory and are connected to the electronic equipment. Through holes for the crimped antenna cables are also provided at factory. These are connected on site with on the antenna carrier mounted coarser antenna cables (feders) connected to the antennas.

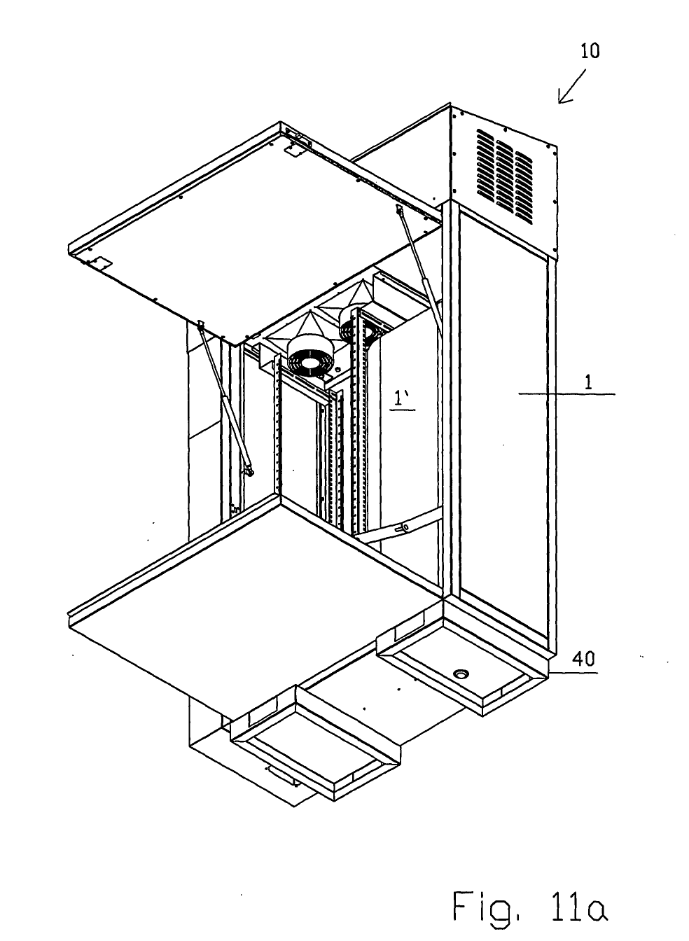

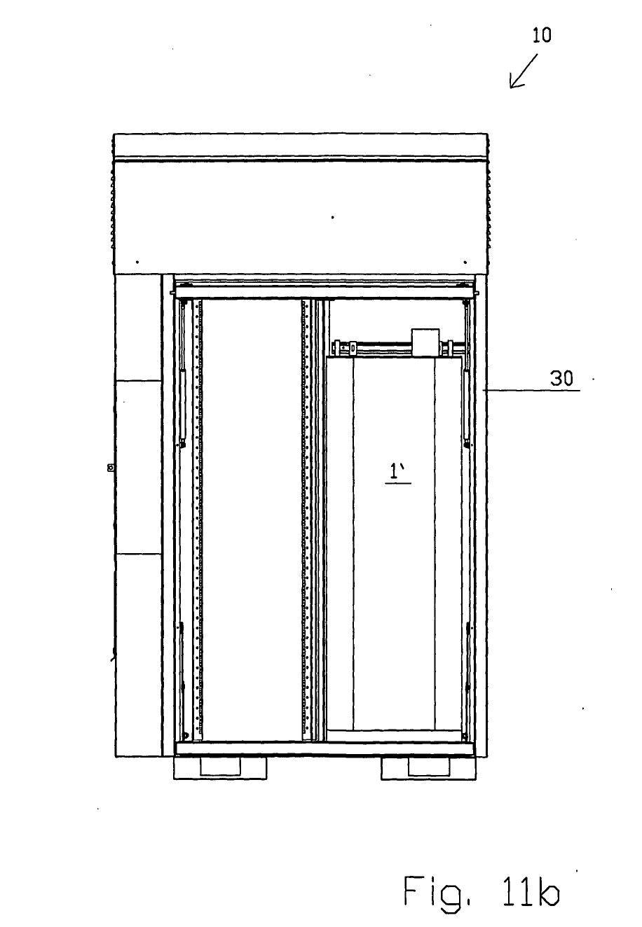

FIG. 11a shows in a perspective view from below from the right, a weather cover 10 according to an embodiment of the present invention, in which it is even more evident how the electronic equipment 3 could be mounted in the housing 1 (of which only the right side seen from a user's point of view comprises mounted electronic equipment). FIG. 11b shows the same embodiment of the weather cover according to the present invention, in which it is evident how the connecting means 36 are arranged above the electronic equipment. In FIG. 11b, the electronic equipment 3 is shown mounted such that it occupies only part of the space provided in the housing 1, whereby the electronic equipment 3 is shown schematically as one RBS (radio base transmitter). In the drawing figure, it is however evident that more, such as two RBS units could be mounted, which is often an advantage according to an aspect of the present invention.

Moreover, it is shown, in both drawing figures, fundaments/fastening means 40 suitable for placing the weather cover directly on the ground, or alternatively fastening the same on an antenna carrier, mast or tower (not shown).

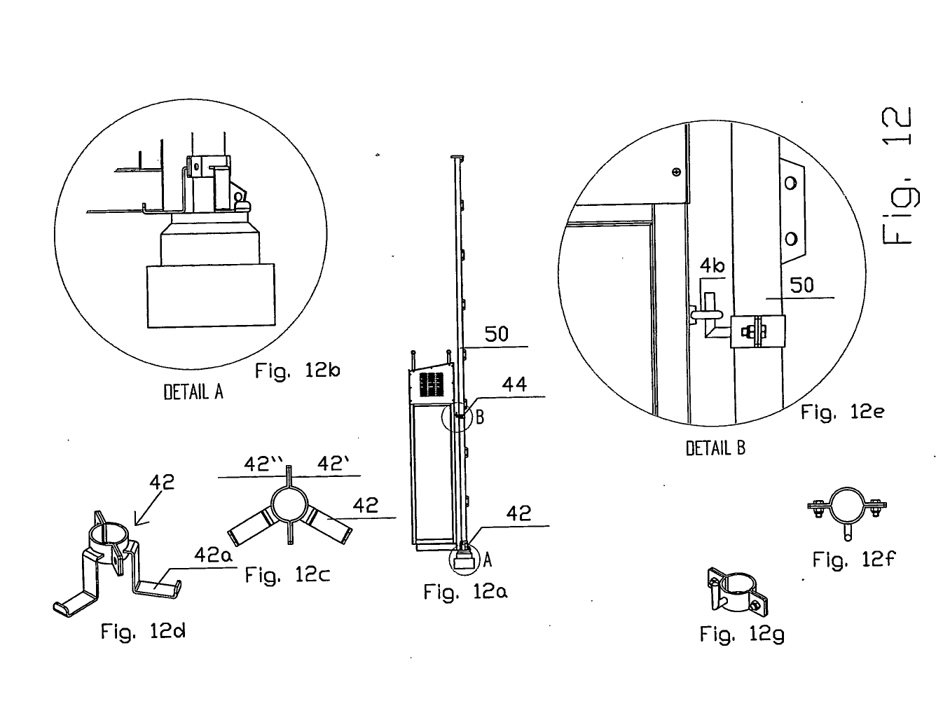

FIG. 12a shows how the weather cover 10 according to an embodiment of the present invention, could be fastened to an antenna carrier 30, mast or tower, by means of lower and upper divided fastening means 42 and 44, each designed such that the semi-parts 42′ and 42′ of the fastening means 42, could be provided around the antenna carrier 30. In FIG. 12b is shown an enlargement of the lower fastening means 42 and how it grips into the lower fastening means 40. The lower two-part fastening means 42 has a substantially L-shaped cross-section having a longer and a shorter side, in which the shorter side 42a preferably is somewhat folded upwards at the tip to retain the lower fastening means 42 when gripping together. Also the upper fastening means 44 has a substantially L-shaped cross-section, preferably of smaller dimension than the lower. The upper fastening means 44 could for instance comprise an L-shaped bar, to its dimension being provided such that it fits into a circular support 46 provided on the side of the protective weather cover 10 to be attached to the antenna carrier 50. The design of the L-shape and function of the fastening means 42, 44 are not described in more detail since it is obvious for a person skilled in the art to dimension these.

According to an even more preferred embodiment of the present invention, the fastening means 42, 44 being divided, comprises at least two L-shaped hanging parts, such that more weather covers could be provided on the same antenna carrier, mast or tower.

By means of using the fastening means according to an embodiment of the present invention, the weather cover according to the present invention, is very well suited for extending already built sites by means of hanging these on the antenna carrier.

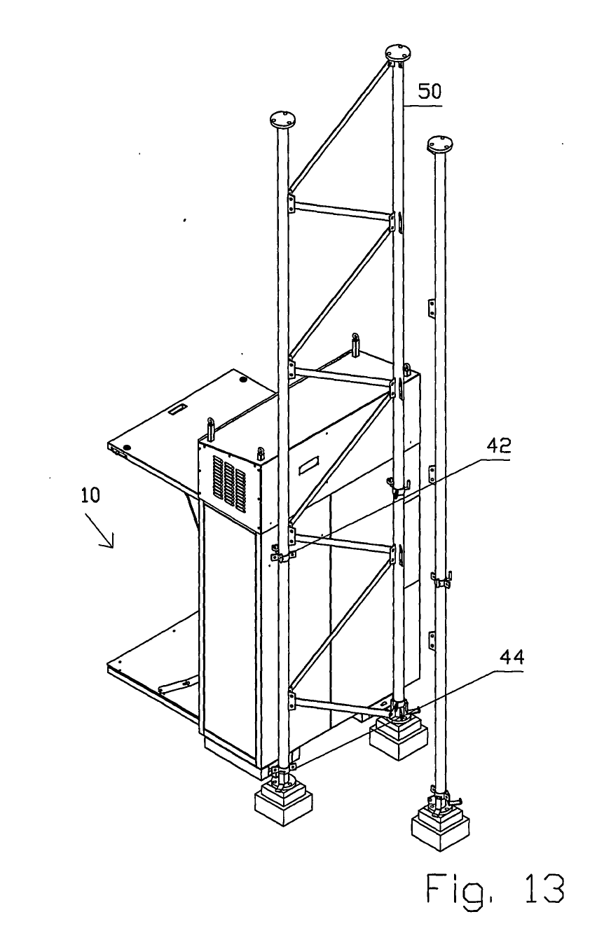

FIG. 13 shows the weather cover according to FIG. 12a in a perspective rear view, in which the arrangement of upper 42 and lower 44 fastening means in relation to the antenna carrier 30 may be provided.

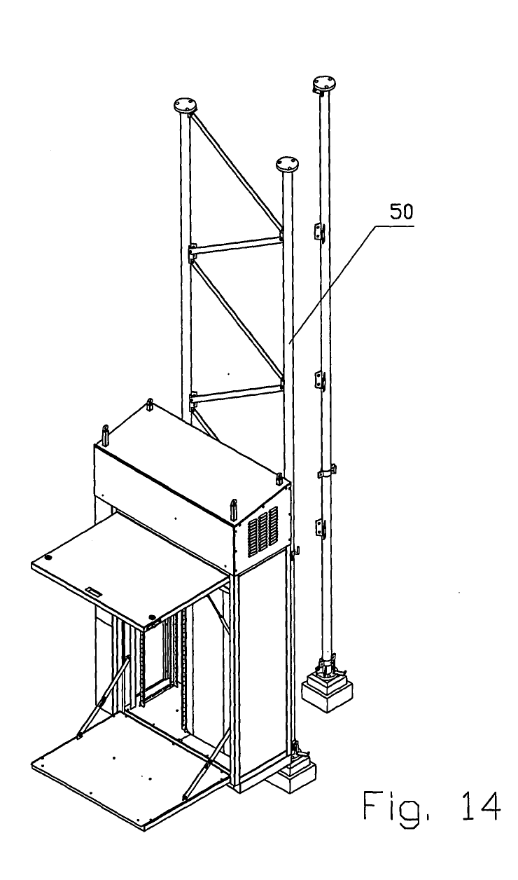

FIG. 14 shows the weather cover according to FIG. 12a in a frontal perspective view and

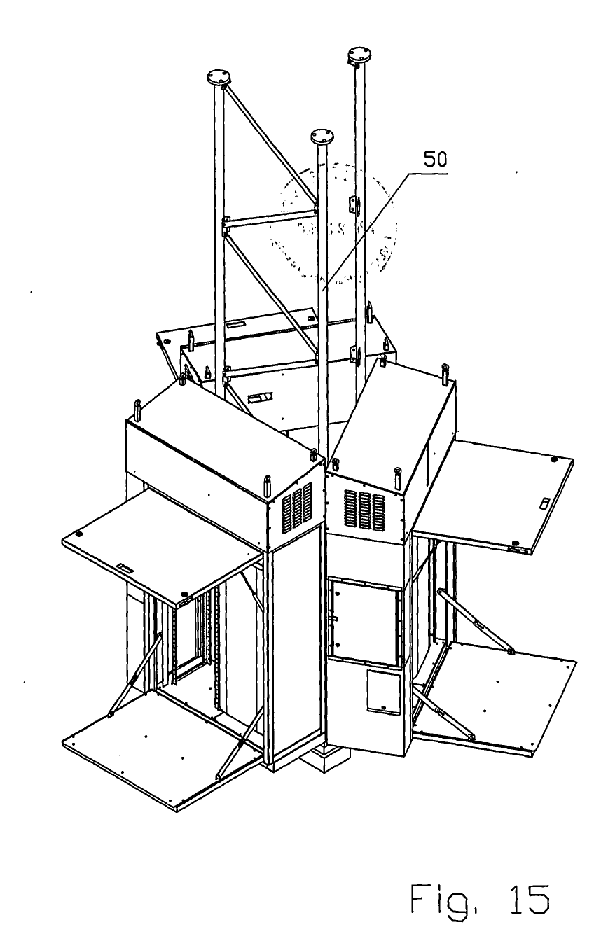

FIG. 15 shows three weather covers 10 mounted on a mast 30.

Even if only electronic equipment for telecommunication such as base station for mobile telephony has been described in relation to the described embodiments, the invention may find application within other fields in which sensitive electronics etc has to be protected such as wide band installations etc. Thus, the examples referring to telecommunication are by no means intended to limit the invention to this particular field only, but only explaining the same.

1. Weather cover for electronic equipment, said weather cover (10) being arranged to be mounted, hanged on masts, towers, buildings or mono-poles, said weather cover (10) comprising:
a protective housing (1) that can be opened for service or the like thereof, said casing (1) comprising at least one side (2) that can be opened, which side (2) comprises at least one door (2a) for access, mounted hinged in the casing (1) such that it provides an opening or closes the casing (1), between electronic equipment mounted therein (3), which weather cover (10) further comprises mounting means for hanging said weather cover (10).

2. Weather cover according to claim 1, which weather cover (10) comprises at least a first door (2a) and a second door (2b), said doors (2a, 2b) being arranged hinged in the housing (1) such that they together provide an opening of or closes the housing (1), characterised in that the doors (2a, 2b) substantially are conform and arranged to from a vertical position turn upwards, and downwards respectively to a substantially horizontal position in respect of the normal position in use of the housing (1), and that movable shielding means (4, 5) when the doors (2a, 2b) are open are provided to connect the thereby obtained free edges of the doors (2a, 2b) and during service of the electronic equipment for instance being arranged to provide a space for the service personnel and together with the housing (1) provide a cover for the electronic equipment (3) as well as for the service personnel.

3. Weather cover according to claim 2, characterised in that the first door (2a) is arranged to provide a roof and the second door (2b) is arranged to provide a floor in an open position in use thereof.

4. Weather cover according to claim 3, characterised in that the movable shielding means (4, 5) are foldable.

5. Weather cover according to claim 4, characterised in that the shielding means (4, 5) comprises at least two parts (4a, 4b, 5a and 5b), which in extended, up-folded position are arranged to provide a surrounding weather cover for users.

6. Weather cover according to claim 2, characterised in that the second door (2b) is provided with locking means (6) for locking the door in an open position, wherein said locking means (6) is/are provided to, in an open position, support at least the load of two persons and electronic equipment (3).

7. Weather cover according to claim 6, characterised in that said locking means (6) comprises at least one foldable bar (6) provided between an edge (7) and the second door (2b) and an inner side (8) of the housing (1), whereby the foldable bar (6) in unfolded position keeps the second door (2b) in a substantially horizontal position.

8. Weather cover according to claim 2, characterised in that the second door (2b) is provided with built-in damping means such as gas attenuators, which are adapted for damping the velocity of the second door (2b) when folded down, and to support folding up the same (2b).

9. Weather cover according to claim 2, characterised in that the second door (2b) is arranged to be foldable towards the ground to provide a ramp for heavy goods, preferably by controlling a locking means, such as a sprint, provided for this.

10. Weather cover according to claim 1, characterised in that the weather cover (10) is provided with a temperature control device (20), which comprises means (23) for temperature control, preferably for cooling the electronic equipment (3) in the weather cover (10), whereby the temperature control device (20) is provided as a wall of the housing (1), preferably the roof and preferably being provided with lifting means (22), such as lifting loops, such that it easily can be removed or mounted to the housing (1).

11. Weather cover according to claim 10, characterised in that the temperature control device (20) is arranged to operate with ambient air as cooling medium or with actively controlled cooling or a combination thereof.

12. Use of at least one weather cover (10) according to claim 1 for mounting on an antenna carrier device, mast, tower or mono-pole.

13. Use of at least two or more weather covers (10) according to claim 12.

14. Antenna carrier 30 for electronic equipment, onto which antenna carrier (30) a weather cover (10) according to claim 1 is mounted and hanged.
